(19) United States
(12) Patent Application Publication
(10) Pub. No.: US 2023/0050506 A1
(43) Pub. Date: Feb. 16, 2023

(54) PLASMA PROCESSING APPARATUS AND PLASMA PROCESSING METHOD

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 17/879,803

(22) Filed: Aug. 3, 2022

(30) Foreign Application Priority Data
Aug. 10, 2021 (JP) 2021-130647
Jun. 30, 2022 (JP) 2022-106154

(51) Int. Cl. H01J 37/32

(52) U.S. Cl. CPC H01J 37/32642; H01J 37/32137; H01J 2237/327

(57) ABSTRACT

There is a plasma processing apparatus comprising: a chamber; a substrate support configured to support a substrate and an edge ring; high-frequency power supply configured to generate first high-frequency power via the substrate and second high-frequency power via the edge ring; and bias power supply configured to generate first electric bias energy supplied to the substrate and second electric bias energy supplied to the edge ring, wherein the first electric bias energy and the second electric bias energy have a waveform repeatedly at a cycle, the cycle includes a first period in which voltage of each of the first and second electric bias energies has a positive level with respect to an average value of the voltage within the cycle, and a second period in which the voltage of each of the first and second electric bias energies has a negative level with respect to the average value.

### CROSS-REFERENCE TO RELATED APPLICATIONS

This application claims priority to Japanese Patent Application Nos. 2021-130647 filed on Aug. 10, 2021 and 2022-106154 filed on Jun. 30, 2022, respectively, the entire contents of each are incorporated herein by reference.

### TECHNICAL FIELD

Exemplary embodiments of the present disclosure relate to a plasma processing apparatus and a plasma processing method.

### BACKGROUND

A plasma processing apparatus is used for plasma processing for a substrate. The plasma processing apparatus includes a chamber and a substrate support. The substrate support is provided in the chamber. The substrate support supports the substrate and an edge ring (or focus ring). A thickness of the edge ring is decreased by the plasma processing. Japanese Laid-open Patent Publication No. 2008-227063 discloses a plasma processing apparatus configured to apply a negative direct current (DC) voltage to the edge ring when the thickness of the edge ring is small. When the negative DC voltage is applied, a sheath on the edge ring becomes thickened, so a difference between a top location of the sheath on the substrate and the top location of the sheath on the edge ring is resolved.

### SUMMARY

The present disclosure provides a technology that reduces a difference between a top location of a sheath on a substrate and a top location of the sheath on an edge ring within a cycle of electric bias energy supplied to the edge ring.

In accordance with an aspect of the present disclosure, there is provided a plasma processing apparatus. The plasma processing apparatus comprises a chamber, a substrate support, at least one high-frequency power supply, and at least one bias power supply. The at least one high-frequency power supply is configured to generate first electric bias energy supplied to the substrate and second electric bias energy supplied to the edge ring. The at least one bias power supply is configured to generate first electric bias energy supplied to the substrate and second electric bias energy supplied to the edge ring. Each of the first electric bias energy and the second electric bias energy has a waveform repeatedly at a cycle having a time length of an inverse number of a bias frequency. The cycle includes a first period and a second period. In the first period, voltage of each of the first electric bias energy and the second electric bias energy has a positive level with respect to an average value of the voltage within the cycle. In the second period, the voltage of each of the first electric bias energy and the second electric bias energy has a negative level with respect to the average value. In the first period, a power level of the first high-frequency power or a power level of the second high-frequency power is set so as to reduce a difference between a top location of a sheath on the substrate and a top location of the sheath on the edge ring.

### BRIEF DESCRIPTION OF THE DRAWINGS

FIG. 1 is a schematic diagram of a plasma processing apparatus according to an exemplary embodiment.

FIG. 2 is a schematic diagram of a plasma processing apparatus according to an exemplary embodiment.

FIG. 3 is a schematic diagram of a plasma processing apparatus according to an exemplary embodiment.

FIG. 4 is a timing chart related to a plasma processing apparatus according to an exemplary embodiment.

FIG. 5A is a diagram illustrating a top location of a sheath when a thickness of an edge ring is larger than a predetermined value, and FIG. 5B is a diagram illustrating the top location of the sheath when the thickness of the edge ring is smaller than the predetermined value.

FIG. 6 is a schematic diagram of a plasma processing apparatus according to another exemplary embodiment.

FIG. 7 is a schematic diagram of a plasma processing apparatus according to yet another exemplary embodiment.

FIG. 8 is a schematic diagram of a plasma processing apparatus according to still yet another exemplary embodiment.

FIG. 9 is a schematic diagram of a plasma processing apparatus according to still yet another exemplary embodiment.

FIG. 10 is a schematic diagram of a plasma processing apparatus according to still yet another exemplary embodiment.

FIG. 11 is a schematic diagram of a plasma processing apparatus according to still yet another exemplary embodiment.

FIG. 12 is a schematic diagram of a plasma processing apparatus according to still yet another exemplary embodiment.

FIG. 13 is a schematic diagram of a plasma processing apparatus according to still yet another exemplary embodiment.

FIG. 14 is a schematic diagram of a plasma processing apparatus according to still yet another exemplary embodiment.

FIG. 15 is a schematic diagram of a plasma processing apparatus according to still yet another exemplary embodiment.

FIG. 16 is a flowchart of a plasma processing method according to an exemplary embodiment.

### DETAILED DESCRIPTION

Hereinafter, various exemplary embodiments will be described in detail with reference to the drawings. Further, in each drawing, the same or equivalent parts will be denoted by the same reference numerals.

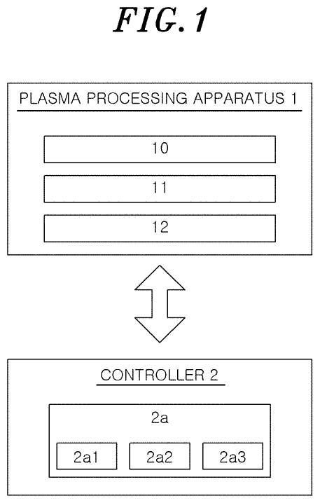

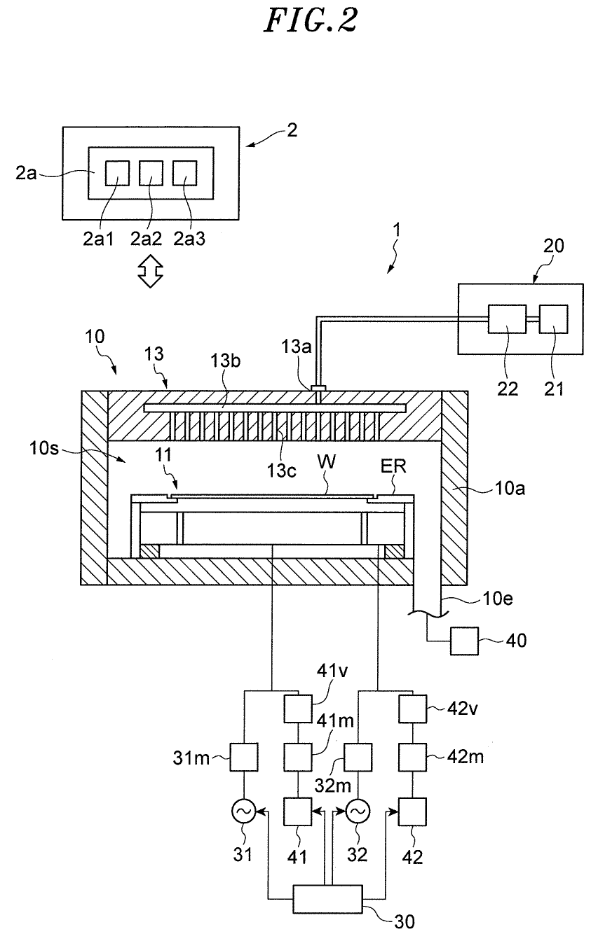

FIGS. 1 and 2 are schematic diagrams of a plasma processing apparatus according to an exemplary embodiment.

In an exemplary embodiment, a plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. Further, the plasma processing chamber 10 includes at least one gas supply port for supplying at least one processing gas to the plasma processing space and at least one discharge port for discharging gas from the plasma processing space. The gas supply port is connected to a gas supply 20 to be described below and the gas discharge port is connected to an exhaust system 40 to be described below. The substrate support 11 is disposed in the plasma processing space, and has a substrate support surface for supporting a substrate.

The plasma generator 12 is configured to generate plasma from at least one processing gas supplied in the plasma processing space. The plasma formed in the plasma processing space may be capacitively coupled plasma (CCP), inductively coupled plasma (ICP), electron-cyclotron-resonance plasma (ECR plasma), helicon wave plasma (HWP), or surface plasma (SWP).

The controller 2 processes a computer executable command which allows the plasma processing apparatus 1 to execute various processes described in the present disclosure. The controller 2 may be configured to control each element of the plasma processing apparatus 1 so as to execute various processes described herein. In an exemplary embodiment, a part or the entirety of the controller 2 may be included in the plasma processing apparatus 1. The controller 2 may include, for example, a computer 2a. The computer 2a may include a central processing unit (CPU) 2a1, a memory 2a2, and a communication interface 2a3, for example. The CPU 2a1 may be configured to perform various control operations based on a program stored in the memory 2a2. The memory 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as local area network (LAN), etc.

Hereinafter, as an example of the plasma processing apparatus 1, an example of a configuration of a capacitively coupled plasma processing apparatus will be described. The plasma processing apparatus 1 includes the plasma processing chamber 10, the gas supply 20, and the exhaust system 40. Further, the plasma processing apparatus 1 includes the substrate support 11 and a gas introduction portion. The gas introduction portion is configured to introduce at least one processing gas into the plasma processing chamber 10. The gas introduction portion includes a shower head 13. The substrate support 11 is disposed in the plasma processing chamber 10. The shower head 13 is disposed above the substrate support 11. In an exemplary embodiment, the shower head 13 constitutes at least a part of a ceiling of the plasma processing chamber 10. The plasma processing chamber 10 includes the shower head 13, a side wall 10a of the plasma processing chamber 10, and a plasma processing space 10s defined by the substrate support 11. The side wall 10a is grounded. The shower head 13 and the substrate support 11 are electrically insulated from a housing of the plasma processing chamber 10.

The substrate support 11 is disposed in the plasma processing chamber 10. The substrate support 11 is configured to support a substrate W and an edge ring ER mounted thereon. The edge ring ER has a ring shape, and is made of a material such as silicon, silicon carbide, and quartz. The substrate W is disposed on the substrate support 11 and in a region surrounded by the edge ring ER. Further, although not illustrated, the substrate support 11 may include a temperature control module configured to control at least one of the substrate W and the edge ring ER at a target temperature. The temperature control module may include a heater, a heating medium, a path, and a combination thereof. In the path, a heating fluid such as brine or gas flows. Further, the substrate support 11 may include a heating gas supply configured to supply heating gas between a back surface of the substrate W and a substrate support surface.

The shower head 13 is configured to introduce at least one processing gas from the gas supply 20 into the plasma processing space 10s. The shower head 13 includes at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c by passing through the gas diffusion chamber 13b. Further, the shower head 13 includes a conductive member. The conductive member of the shower head 13 serves as an upper electrode. Further, the gas introduction portion may include one or a plurality of side gas injectors (SGI) installed in one or a plurality of openings formed on the side wall 10a in addition to the shower head 13.

The gas supply 20 may include one or more gas sources 21 and one or more flow controllers 22. In an exemplary embodiment, the gas supply 20 is configured to supply one or more processing gas to the shower head 13 from the gas sources 21 corresponding to the one or more processing gas, respectively, through the flow controllers 22 corresponding thereto, respectively. Each flow controller 22 may include, for example, a mass-flow controller or a pressure control type flow controller. Further, the gas supply 20 may include one or more flow modulation devices which modulate or pulse the flow of one or more processing gas.

The exhaust system 40 may be connected to a gas outlet 10e provided on a bottom of the plasma processing chamber 10, for example. The exhaust system 40 may include a pressure adjustment valve and a vacuum pump. By the pressure adjustment valve, pressure in the plasma processing space 10s is adjusted. The vacuum pump may include a turbo molecule pump, a dry pump, or a combination thereof.

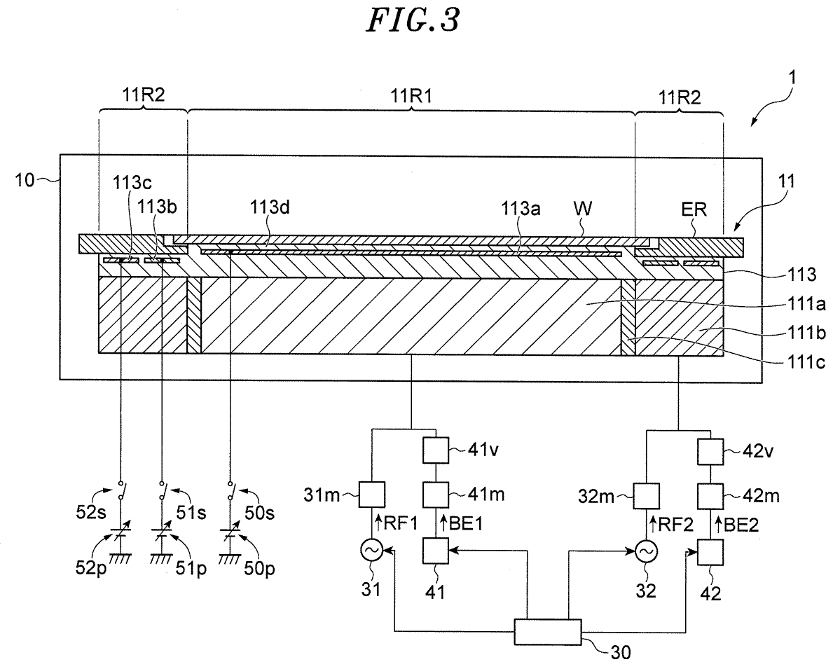

Hereinafter, in addition to FIG. 2, FIG. 3 will be referenced. FIG. 3 is a schematic diagram of a plasma processing apparatus according to an exemplary embodiment. The substrate support 11 includes a first base 111a, a second base 111b, and an electrostatic chuck 113. The first base 111a and the second base 111b are made of a conductor such as aluminum. The first base 111a has a substantially disk shape. The second base 111b has a substantially ring shape. The second base 111b extends in a circumferential direction outside a diameter direction of the first base 111a so as to surround the first base 111a. A dielectric region 111c may be interposed between the first base 111a and the second base 111b.

The electrostatic chuck 113 is provided on the first base 111a and the second base 111b. The substrate support 11 includes a first region 11R1 constituted by a center of the electrostatic chuck 113 and the first base 111a. The substrate W is mounted on the first region 11R1 and on the electrostatic chuck 113. The substrate support 11 includes a second region 11R2 constituted by a peripheral portion of the electrostatic chuck 113 and the second base 111b. The edge ring ER is mounted on the second region 11R2 and on the electrostatic chuck 113.

The electrostatic chuck 113 has a dielectric portion 113d. The dielectric portion 113d is made of a dielectric such as aluminum nitride or aluminum oxide. The dielectric portion 113d has the substantially disk shape. The first region 11R1 includes the center of the dielectric portion 113d. The second region 11R2 includes the periphery of the dielectric portion 113d.

The electrostatic chuck 113 further has a chuck electrode 113a. The chuck electrode 113a is a film made of the conductor, and is provided inside the dielectric portion 113d in the first region 11R1. A direct current (DC) power supply 50p is electrically connected to the chuck electrode 113a via a switch 50s. When DC voltage from the DC power supply 50p is applied to the chuck electrode 113a, an electrostatic gravitation is generated between the substrate W and the electrostatic chuck 113. By the generated electrostatic gravitation, the substrate W is pulled to the electrostatic chuck 113 and held by the electrostatic chuck 113.

The electrostatic chuck 113 may further have chuck electrodes 113b and 113c. Each of the chuck electrodes 113b and 113c is a film formed by the conductor. The chuck electrodes 113b and 113c may have the ring shape. The chuck electrodes 113b and 113c are provided inside the dielectric portion 113d in the second region 11R2. A DC power supply 51p is electrically connected to the chuck electrode 113b via a switch 51s. A DC power supply 52p is electrically connected to the chuck electrode 113c via a switch 52s. When DC voltage from the DC power supply 51p is applied to the chuck electrode 113b and DC voltage from the DC power supply 52p is applied to the chuck electrode 113c, the electrostatic gravitation is generated between the edge ring ER and the electrostatic chuck 113. By the generated electrostatic gravitation, the edge ring ER is pulled to the electrostatic chuck 113 and held by the electrostatic chuck 113.

The plasma processing apparatus 1 includes a high-frequency power supply 31 (first high-frequency power supply), a high-frequency power supply 32 (second high-frequency power supply), a bias power supply 41 (first bias power supply), and a bias power supply 42 (second bias power supply).

The high-frequency power supply 31 is configured to generate a high-frequency power RF1 (first high-frequency power) to generate plasma in the chamber 10. The high-frequency power RF1 has, for example, a frequency of 13 MHz or more and 150 MHz or less. The high-frequency power RF1 is supplied to the substrate support 11 so as to be coupled to the plasma on the substrate W via the substrate support 11 and the substrate W. In the exemplary embodiment of FIG. 3, the high-frequency power supply 31 is electrically connected to the first base 111a via a matcher 31m. The matcher 31m includes a matching circuit. The matching circuit of the matcher 31m has a variable impedance. The matching circuit of the matcher 31m is controlled by the controller 30 to be described below. The impedance of the matching circuit of the matcher 31m is adjusted to match a load-side impedance of the high-frequency power supply 31 with an output impedance of the high-frequency power supply 31.

The high-frequency power supply 32 is configured to generate a high-frequency power RF2 (second high-frequency power) to generate plasma in the chamber 10. The high-frequency power RF2 has a frequency that is equal to the high-frequency power RF1, for example, a frequency of 13 MHz or more and 150 MHz or less. The high-frequency power RF2 is supplied to the substrate support 11 so as to be coupled to the plasma on the edge ring ER via the substrate support 11 and the edge ring ER. In the exemplary embodiment of FIG. 3, the high-frequency power supply 32 is electrically connected to the second base 111b via a matcher 32m. The matcher 32m includes a matching circuit. The matching circuit of the matcher 32m has a variable impedance. The matching circuit of the matcher 32m is controlled by the controller 30. The impedance of the matching circuit of the matcher 32m is adjusted to match the load-side impedance of the high-frequency power supply 32 with the output impedance of the high-frequency power supply 32.

The bias power supply 41 is configured to generate electric bias energy BE1 (first electric bias energy). The electric bias energy BE1 is supplied to the substrate W via the substrate support 11. The electric bias energy BE1 is supplied to the substrate W to adjust the energy of ions supplied from the plasma to the substrate W. In the exemplary embodiment of FIG. 3, the bias power supply 41 is electrically connected to the first base 111a.

The bias power supply 42 is configured to generate electric bias energy BE2 (second electric bias energy). The electric bias energy BE2 is supplied to the edge ring ER via the substrate support 11. The electric bias energy BE2 is supplied to the edge ring ER to adjust the energy of ions supplied from the plasma to the edge ring ER. In the exemplary embodiment of FIG. 3, the bias power supply 42 is electrically connected to the second base 111b.

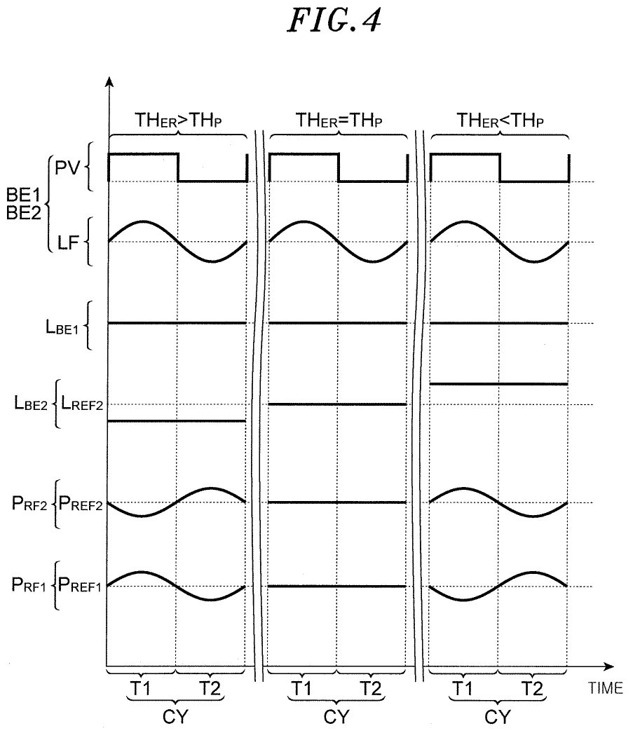

Hereinafter, FIG. 4 is referenced jointly with FIGS. 2 and 3. FIG. 4 is a timing chart related to a plasma processing apparatus according to an exemplary embodiment. In FIG. 4, a waveform (voltage waveform) of each of the electric bias energy BE1 and the electric bias energy BE2 is illustrated. Further, in FIG. 4, a level L_{BE1} of the electric bias energy BE1 and a level L_{BE2} of the electric bias energy BE2 are illustrated. Further, in FIG. 4, a power level P_{RF1} of the high-frequency power RF1 and a power level P_{RF2} of the high-frequency power RF2 are illustrated.

Each of the electric bias energy BE1 and the electric bias energy BE2 has a waveform repeated at a cycle CY (waveform cycle) having a time length of an inverse number of a bias frequency. The bias frequency is, for example, a frequency of 100 kHz or more and 13.56 MHz or less.

In an exemplary embodiment, each of the electric bias energy BE1 and the electric bias energy BE2 may be high-frequency power having the bias frequency i.e., high-frequency bias power LF. The high-frequency bias power LF has a waveform having a sinusoidal wave shape at a cycle CY (waveform cycle), i.e., a bias cycle. The cycle CY has the time length of the inverse number of the bias frequency.

When the electric bias energy BE1 is the high-frequency bias power LF, the bias power supply 41 is connected to the first base 111a via a matcher 41m. The matcher 41m includes a matching circuit. The matching circuit of the matcher 41m has a variable impedance. The matching circuit of the matcher 41m is controlled by the controller 30. The impedance of the matching circuit of the matcher 41m is adjusted to match the load-side impedance of the bias power supply 41 with the output impedance of the bias power supply 41.

When the electric bias energy BE2 is the high-frequency bias power LF, the bias power supply 42 is connected to the second base 111b via a matcher 42m. The matcher 42m includes a matching circuit. The matching circuit of the matcher 42m has a variable impedance. The matching circuit of the matcher 42m is controlled by the controller 30. The impedance of the matching circuit of the matcher 42m is adjusted to match the load-side impedance of the bias power supply 42 with the output impedance of the bias power supply 42.

In another exemplary embodiment, each of the electric bias energy BE1 and the electric bias energy BE2 may be a pulse PV of voltage periodically generated at a time interval (i.e., the cycle CY or waveform cycle) having the time length which is the inverse number of the bias frequency. The pulse PV of the voltage used as the electric bias energy BE1 and the electric bias energy BE2 may be a pulse of negative voltage or a pulse of negative DC voltage. The pulse PV of the voltage may have a predetermined waveform such as a triangular wave or a rectangular wave. When the pulse of the voltage is used as the electric bias energy BE1, a filter may be connected to the bias power supply 41 to interrupt the high-frequency power instead of the matcher 41m. Further, when the pulse of the voltage is used as the electric bias energy BE2, the filter may be connected to the bias power supply 42 to interrupt the high-frequency power instead of the matcher 42m.

The cycle CY (waveform cycle) includes a first period T1 and a second period T2. In the first period T1, the voltage of each of the electric bias energy BE1 and the electric bias energy BE2 has a positive level for an average value of the corresponding voltage within the cycle CY. In the second period T2, the voltage of each of the electric bias energy BE1 and the electric bias energy BE2 has a negative level for the corresponding average value.

The high-frequency power supply 31 may change the frequency of the high-frequency power RF1 within the cycle CY in order to suppress reflection from the load of the high-frequency power RF1. To this end, the cycle CY is divided into multiple phase periods. The frequency of the high-frequency power RF1 of each of multiple phase periods within the cycle CY is set by using a time series of a frequency prepared in advance. The time series of the frequency may be designated to the high-frequency power supply 31 from the controller 30.

Further, the high-frequency power supply 32 may change the frequency of the high-frequency power RF2 within the cycle CY in order to suppress reflection from the load of the high-frequency power RF2. The frequency of the high-frequency power RF2 of each of multiple phase periods within the cycle CY is set by using the time series of the frequency prepared in advance. The time series of the frequency may be designated to the high-frequency power supply 32 from the controller 30.

The controller 30 is configured to control the high-frequency power supply 31, the high-frequency power supply 32, the bias power supply 41, and the bias power supply 42. The controller 30 may be configured as a processor such as a CPU. Further, a controller 2 may also serve as the controller 30.

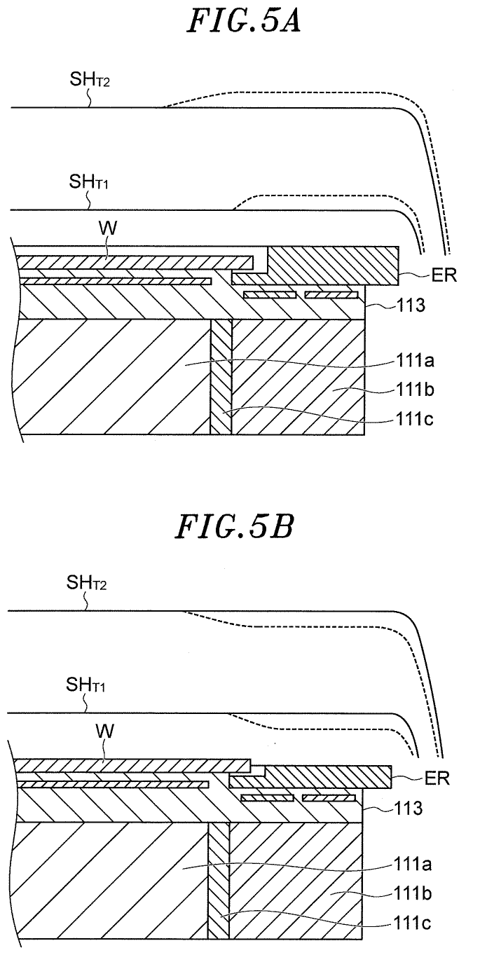

Hereinafter, FIGS. 5A and 5B are referenced jointly with FIGS. 2 to 4. FIG. 5A is a diagram illustrating a top location of a sheath when a thickness of an edge ring is larger than a predetermined value, and FIG. 5B is a diagram illustrating the top location of the sheath when the thickness of the edge ring is smaller than the predetermined value.

As illustrated in FIGS. 5A and 5B, the thickness of the sheath is small in the first period T1 and a location of a top SH_{T1} of the sheath in the first period T1 is low. Meanwhile, the thickness of the sheath in the second period T2 is large and the location of the top SH_{T2} of the sheath in the second period T2 is high. Further, the location (i.e., a top location of the sheath) of the top of the sheath is a height-direction location/position of an interface between the sheath and the plasma.

When a thickness TH_{ER} of the edge ring ER is a predetermined value TH_{P}, for example, when a height-direction location of the top of the edge ring ER and the height-direction location of the top of the substrate W are the same as each other, the top location of the sheath on the edge ring ER is the same as the top location of the sheath on the substrate W. Hereinafter, the level L_{BE2} of the electric bias energy BE2 in this case will be referred to as a reference level L_{REF2} Further, the power level P_{RF1} of the high-frequency power RF1 in this case will be referred to as a reference power level P_{REF1}. Further, the power level P_{RF2} of the high-frequency power RF2 in this case will be referred to as a reference power level P_{REF2}.

When the thickness TH_{ER} of the edge ring ER is larger than the predetermined value TH_{P}, and the level L_{BE2} is the reference level L_{REF2}, the top location of the sheath on the edge ring ER becomes higher than the top location of the sheath on the substrate W as indicated by a broken line in FIG. 5A. When the thickness TH_{ER} of the edge ring ER is smaller than the predetermined value TH_{P}, and the level L_{BE2} is the reference level L_{REF2}, the top location of the sheath on the edge ring ER becomes lower than the top location of the sheath on the substrate W as indicated by the broken line in FIG. 5B.

In the plasma processing apparatus 1, the level L_{BE2} of the electric bias energy BE2 is adjusted to reduce the difference between the top location of the sheath on the substrate W and the top location of the sheath on the edge ring ER within the cycle CY. Further, the power level P_{RF1} of the high-frequency power RF1 and/or the power level P_{RF2} of the high-frequency power RF2 are/is adjusted. The level L_{BE2} of the electric bias energy BE2, and the power level P_{RF1} of the high-frequency power RF1 and the power level P_{RF2} of the high-frequency power RF2 may be controlled by the controller 30.

In the second period T2, the thickness of the sheath on the substrate W and the thickness of the sheath on the edge ring ER are determined mainly by the level L_{BE1} of the electric bias energy BE1 and the level L_{BE2} of the electric bias energy BE2. In the second period T2, the level L_{BE2} of the electric bias energy BE2 is set to increase with a decrease in thickness TH_{ER} of the edge ring ER to reduce the difference between the top location of the sheath on the substrate W and the top location of the sheath on the edge ring ER. The level L_{BE2} of the electric bias energy BE2 may be specified as the bias power 42 from the controller 30.

Specifically, when the thickness TH_{ER} of the edge ring ER is larger than the predetermined value TH_{P}, the level L_{BE2} is set to a lower level than the reference level L_{REF2}, as illustrated in FIG. 4. As a result, the difference between the location of a top SH_{T2} of the sheath on the substrate W and the location of the top SH_{T2} of the sheath on the edge ring ER is reduced, as indicated by a solid line in FIG. 5A. Further, the thickness TH_{ER} of the edge ring ER may be optically or electrically acquired by a sensor. Alternatively, the thickness TH_{ER} of the edge ring ER may be estimated from a length of a time for which the edge ring ER is exposed to the plasma.

Meanwhile, when the thickness TH_{ER} of the edge ring ER is smaller than the predetermined value TH_{P}, the level L_{BE2} is set to a higher level than the reference level L_{REF2}, as illustrated in FIG. 4. As a result, the difference between the location of a top SH_{T2} of the sheath on the substrate W and the location of the top SH_{T2} of the sheath on the edge ring ER is reduced, as indicated by the solid line in FIG. 5B.

Further, the higher the level of L_{BE1} of the electric bias energy BE1, the larger an absolute value of a negative bias potential of the substrate W, and the larger the thickness of the sheath on the substrate W. Further, the higher the level of L_{BE2} of the electric bias energy BE2, the larger the absolute value of the negative bias potential of the edge ring ER, and the larger the thickness of the sheath on the edge ring ER. When the electric bias energy BE1 is the high-frequency bias power LF, the level L_{BE1} is the power level of the electric bias energy BE1. When the electric bias energy BE2 is the high-frequency bias power LF, the level L_{BE2} is the power level of the electric bias energy BE2. When the electric bias energy BE1 is the pulse PV of the voltage, the level L_{BE1} increases as the voltage PV increases in a negative direction of the voltage level. Further, when the electric bias energy BE2 is the pulse PV of the voltage, the level L_{BE2} increases as the voltage PV of the voltage increases in the negative direction of the voltage level.

In the first period T1, the thickness of the sheath on the substrate W and the thickness of the sheath on the edge ring ER are determined mainly by the power level P_{RF1} of the high-frequency power RF1 and the power level P_{RF2} of the high-frequency power RF2. In the plasma processing apparatus 1, the power level P_{RF1} or the power level P_{RF2} in the first period T1 is set to reduce the difference between the top location of the sheath on the substrate W and the top location of the sheath on the edge ring ER in the first period T1. The power level P_{RF1} and the power level P_{RF2} are designated to the high-frequency power supply 31 and the high-frequency power supply 32, respectively from the controller 30.

In the plasma processing apparatus 1, in order to adjust the power level P_{RF1} and the power level P_{RF2} within the period CY, the high-frequency power supply 31, the high-frequency power supply 32, the bias power supply 41, and the bias power supply 42 are synchronized with each other using synchronous signals. The synchronous signals may be transmitted to other power supplies from one of the high-frequency power supply 31, the high-frequency power supply 32, the bias power supply 41, and the bias power supply 42. Alternatively, the synchronous signals may be transmitted to the high-frequency power supply 31, the high-frequency power supply 32, the bias power supply 41, and the bias power supply 42 from the controller 30. The synchronous signals may be generated by the controller 30 from the voltage of the electric bias energy BE1 measured by a voltage sensor 41v or the voltage of the electric bias energy BE2 measured by a voltage sensor 42v.

Further, the first period t1 and the second period T2 may be specified from the voltage of the electric bias energy BE1 measured by the voltage sensor 41v or the voltage of the electric bias energy BE2 measured by the voltage sensor 42V by the controller 30. Alternatively, each of the first period T1 and the second period T2 may be set as a period within a cycle CY having a predetermined time length.

Hereinafter, first to fourth examples regarding the adjustment of the power level P_{RF1} and the power level P_{RF2} in the cycle CY will be described.

### First Example

In the first example, when the thickness TH_{ER} of the edge ring ER is larger than the predetermined value TH_{P}, the power level P_{RF2} in the first period T1 is set to be lower than the reference power level P_{REF2}, as illustrated in FIG. 4. As a result, the difference between the location of the top SH_{T1} of the sheath on the substrate W and the location of the top SH_{T1} of the sheath on the edge ring ER is reduced, as indicated by the solid line in FIG. 5A. Further, when the thickness TH_{ER} of the edge ring ER is larger than the predetermined value TH_{P}, the power level P_{RF2} in the second period T2 may be set to be higher than the reference power level P_{REF2}, as illustrated in FIG. 4. As a result, the reduced power level P_{RF2} in the first period T1 is supplemented in the second period T2, and an average plasma density in the cycle CY is maintained at a constant density.

### Second Example

In the second example, when the thickness TH_{ER} of the edge ring ER is larger than the predetermined value TH_{P}, the power level P_{RF1} in the first period T1 is set to be higher than the reference power level P_{REF1}, as illustrated in FIG. 4. As a result, the difference between the location of the top SH_{T1} of the sheath on the substrate W and the location of the top SH_{T1} of the sheath on the edge ring ER is reduced. Further, when the thickness TH_{ER} of the edge ring ER is larger than the predetermined value TH_{P}, the power level P_{RF1} in the second period T2 may be set to be lower than the reference power level P_{REF1}, as illustrated in FIG. 4. As a result, the average power level P_{RF1} in the cycle CY is maintained at a constant power level, and the average plasma density in the cycle CY is maintained at a constant density.

### Third Example

In the third example, when the thickness TH_{ER} of the edge ring ER is smaller than the predetermined value TH_{P}, the power level P_{RF2} in the first period T1 is set to be higher than the reference power level P_{REF2}, as illustrated in FIG. 4. As a result, the difference between the location of the top SH_{T1} of the sheath on the substrate W and the location of the top SH_{T1} of the sheath on the edge ring ER is reduced, as indicated by the solid line in FIG. 5B. Further, when the thickness TH_{ER} of the edge ring ER is smaller than the predetermined value TH_{P}, the power level P_{RF2} in the second period T2 may be set to be lower than the reference power level P_{REF2}, as illustrated in FIG. 4. As a result, the average power level P_{RF2} in the cycle CY is maintained at a constant power level, and the average plasma density in the cycle CY is maintained at a constant density.

### Fourth Example

In the fourth example, when the thickness TH_{ER} of the edge ring ER is smaller than the predetermined value TH_{P}, the power level P_{RF1} in the first period T1 is set to be lower than the reference power level P_{REF1}, as illustrated in FIG. 4. As a result, the difference between the location of the top SH_{T1} of the sheath on the substrate W and the location of the top SH_{T1} of the sheath on the edge ring ER is reduced. Further, when the thickness TH_{ER} of the edge ring ER is smaller than the predetermined value TH_{P}, the power level P_{RF1} in the second period T2 may be set to be higher than the reference power level P_{REF1}, as illustrated in FIG. 4. As a result, the reduced power level P_{RF1} in the first period T1 is supplemented in the second period T2, and the average plasma density in the cycle CY is maintained at a constant density.

In the plasma processing apparatus 1 described above, by adjusting the level of the second electric bias energy, it is possible to reduce the difference between the top location of the sheath on the substrate W and the top location of the sheath on the edge ring ER in the second period of the period CY. Further, in the first period T1, the power level P_{RF1} of the high-frequency power RF1 or the power level P_{RF2} of the high-frequency power RF2 is set so as to reduce the difference between the top location of the sheath on the substrate W and the top location of the sheath on the edge ring ER. Therefore, in the first period T1, it is possible to reduce the difference between the top location of the sheath on the substrate W and the top location of the sheath on the edge ring ER. Therefore, according to the plasma processing apparatus 1, in the cycle CY of the electric bias energy BE2 supplied to the edge ring ER, it is possible to reduce the difference between the top location of the sheath on the substrate W and the top location of the sheath on the edge ring ER.

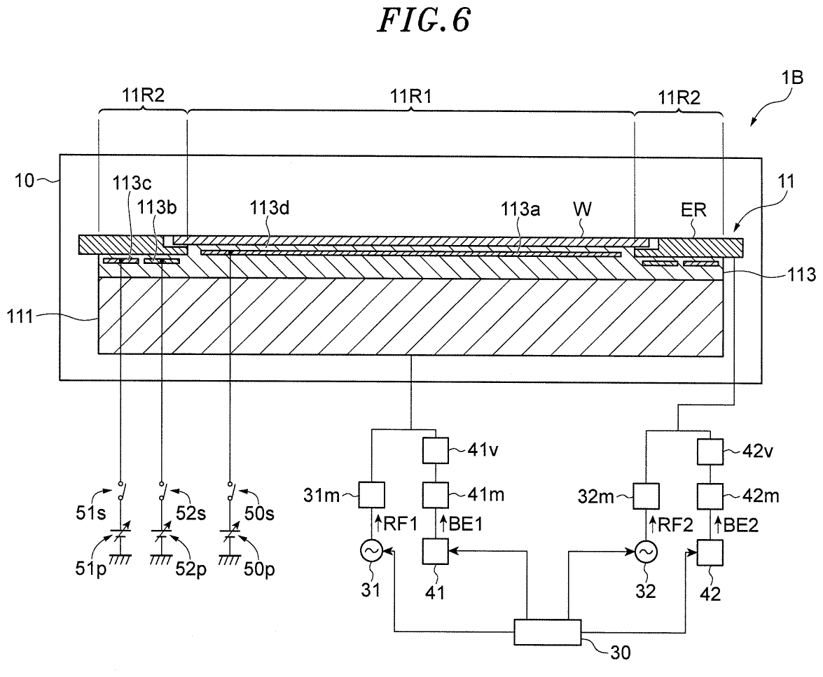

Hereinafter, a plasma processing apparatus according to some other exemplary embodiments will be described with reference to FIGS. 6 to 14. FIG. 6 is a schematic diagram of a plasma processing apparatus according to another exemplary embodiment. Hereinafter, a difference between the plasma processing apparatus 1B illustrated in FIG. 6 and the plasma processing apparatus 1 will be described.

The plasma processing apparatus 1B includes a base 111 instead of the first base 111a and the second base 111b. The base 111 has the substantially disk shape, and is made of a conductor such as aluminum. The electrostatic chuck 113 is provided on the base 111. In the plasma processing device 1B, the high-frequency power supply 31 and the bias power supply 41 are electrically connected to the base 111. The high-frequency power supply 31 and the bias power supply 41 are electrically connected to the edge ring ER. The other configuration of the plasma processing apparatus 1B is the same as the corresponding configuration of the plasma processing apparatus 1. Further, an operation of each component of the plasma processing apparatus 1B is the same as the operation of the corresponding part of the plasma processing apparatus 1.

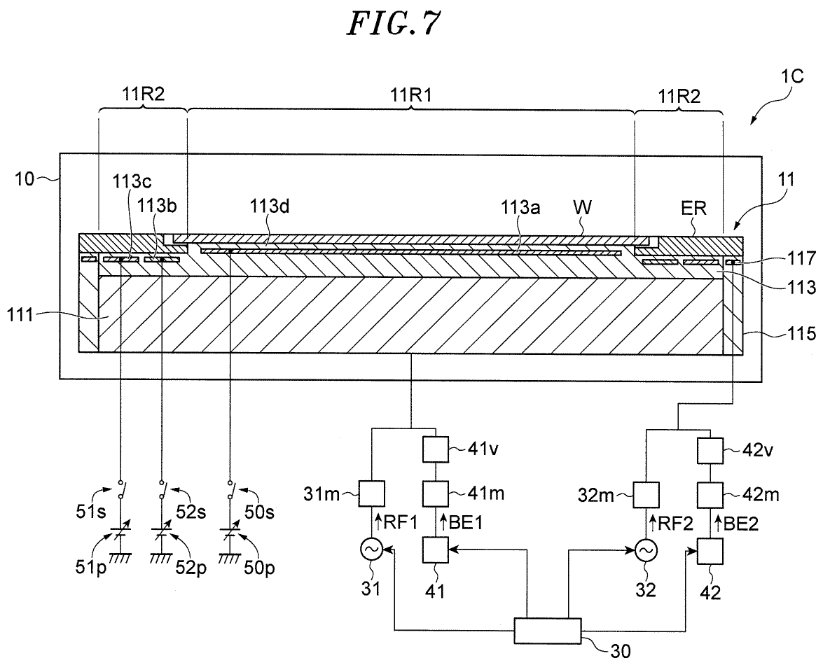

FIG. 7 is a schematic diagram of a plasma processing apparatus according to still yet another exemplary embodiment. Hereinafter, the difference of the plasma processing apparatus 1C illustrated in FIG. 7 from the plasma processing apparatus 1B will be described.

The plasma processing apparatus 1C includes an insulating portion 115 provided to surround the base 111. The insulating portion 115 is made of an insulator such as quartz. The periphery of the edge ring ER is mounted on the insulating portion 115. An electrode 117 is provided inside the insulating portion 115. The electrode 117 may be extended in the circumference direction or may have a ring shape. The electrode 117 is disposed below the periphery of the edge ring ER. In the plasma processing device 1C, the high-frequency power supply 32 and the bias power supply 42 are electrically connected to the electrode 117. The other configuration of the plasma processing apparatus 1C is the same as the corresponding configuration of the plasma processing apparatus 1B. Further, the operation of each component of the plasma processing apparatus 1C is the same as the operation of the corresponding part of the plasma processing apparatus 1B.

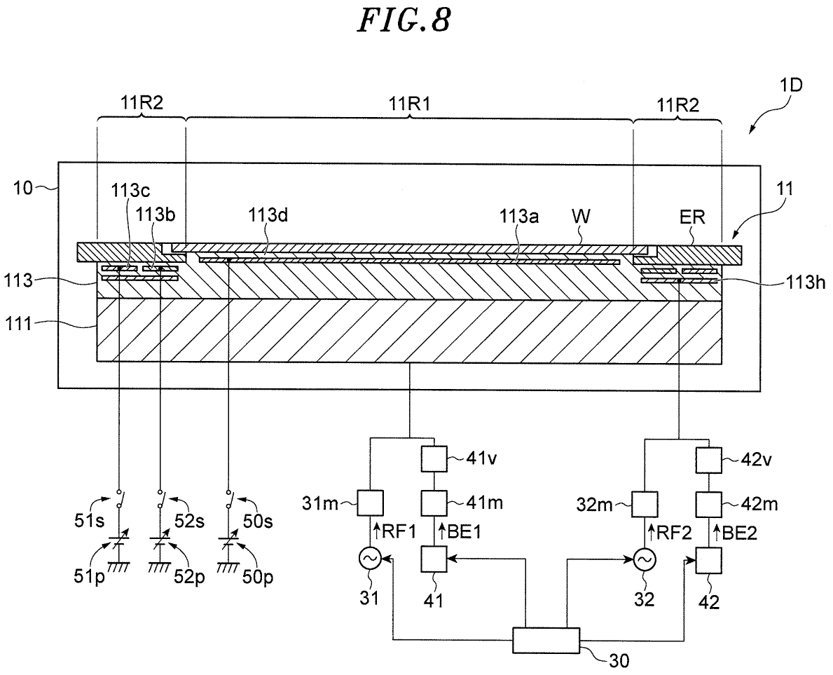

FIG. 8 is a schematic diagram of a plasma processing apparatus according to still yet another exemplary embodiment. Hereinafter, the difference of the plasma processing apparatus 1C illustrated in FIG. 8 from the plasma processing apparatus 1B will be described.

In the plasma processing apparatus 1D, an electrode 113h is provided inside a dielectric portion 113d of the electrostatic chuck 113 in the second region 11R2. The electrode 113h is the film formed by the conductor. The electrode 113h may be extended in the circumference direction or may have the ring shape. The electrode 113h may be provided between each of the chuck electrodes 113b and 113c and a lower surface of the dielectric portion 113d. In the plasma processing apparatus 1D, the high-frequency power supply 32 and the bias power supply 42 are electrically connected to the electrode 113h. The other configuration of the plasma processing apparatus 1D is the same as the corresponding configuration of the plasma processing apparatus 1B. Further, the operation of each component of the plasma processing apparatus 1D is the same as the operation of the corresponding part of the plasma processing apparatus 1B.

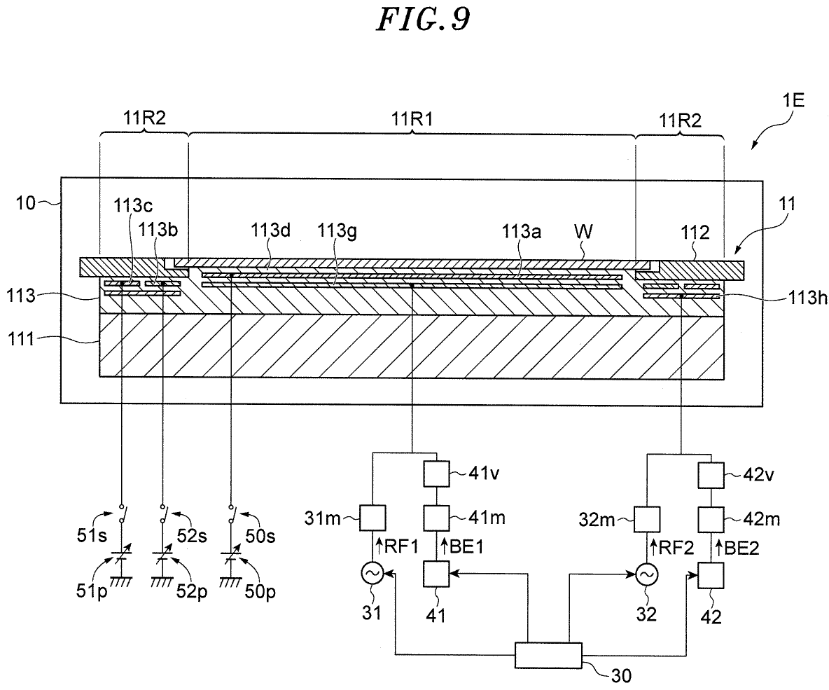

FIG. 9 is a schematic diagram of a plasma processing apparatus according to still yet another exemplary embodiment. Hereinafter, the difference of the plasma processing apparatus 1E illustrated in FIG. 9 from the plasma processing apparatus 1D will be described.

In the plasma processing apparatus 1E, an electrode 113g is provided inside the dielectric portion 113d of the electrostatic chuck 113 in the first region 11R1. The electrode 113g is the film formed by the conductor. The electrode 113g may have a circular shape. The electrode 113g may be provided between the chuck electrodes 113a and 113c and the lower surface of the dielectric portion 113d. In the plasma processing device 1E, the high-frequency power supply 31 and the bias power supply 41 are electrically connected to the electrode 113g. The other configuration of the plasma processing apparatus 1E is the same as the corresponding configuration of the plasma processing apparatus 1D. Further, the operation of each component of the plasma processing apparatus 1E is the same as the operation of the corresponding part of the plasma processing apparatus 1D. Further, in the plasma processing apparatus 1E, the base 111 may be made of any one of the conductor, the dielectric, or the semiconductor.

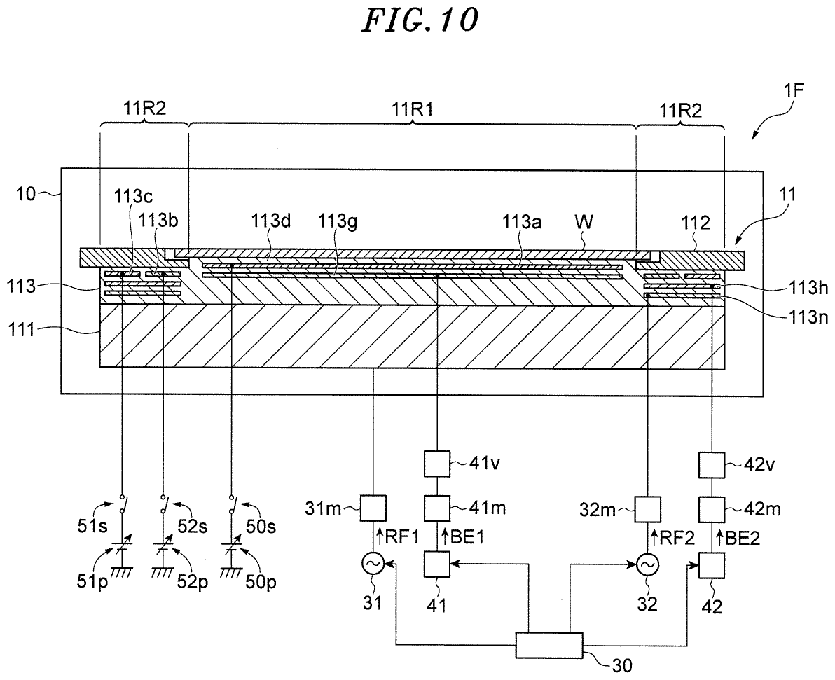

FIG. 10 is a schematic diagram of a plasma processing apparatus according to still yet another exemplary embodiment. Hereinafter, the difference of the plasma processing apparatus 1F illustrated in FIG. 10 from the plasma processing apparatus 1E will be described.

In the plasma processing apparatus 1F, an electrode 113n is provided inside the dielectric portion 113d of the electrostatic chuck 113 in the second region 11R2. The electrode 113n is the film formed by the conductor. The electrode 113n may be extended in the circumference direction or may have the ring shape. The electrode 113n may be provided between the electrode 113h and the lower surface of the dielectric portion 113d. In the plasma processing apparatus 1F, the high-frequency power supply 32 may be electrically connected to the electrode 113n. The other configuration of the plasma processing apparatus 1F is the same as the corresponding configuration of the plasma processing apparatus 1E. Further, the operation of each component of the plasma processing apparatus 1F is the same as the operation of the corresponding part of the plasma processing apparatus 1E.

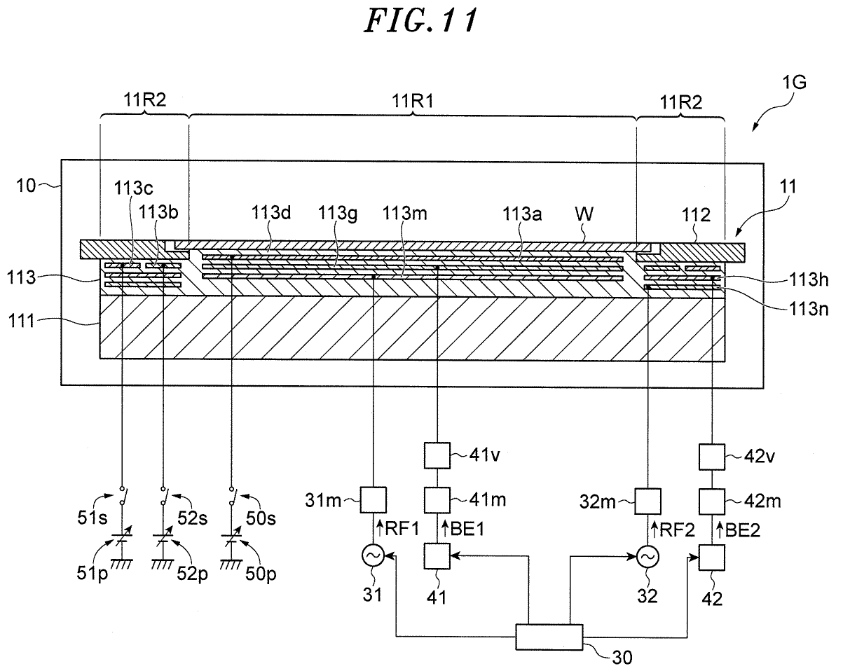

FIG. 11 is a schematic diagram of a plasma processing apparatus according to still yet another exemplary embodiment. Hereinafter, the difference of the plasma processing apparatus 1G illustrated in FIG. 11 from the plasma processing apparatus 1F will be described.

In the plasma processing apparatus 1G, an electrode 113m is provided inside the dielectric portion 113d of the electrostatic chuck 113 in the first region 11R1. The electrode 113m is the film formed by the conductor. The electrode 113m may have the circular shape. The electrode 113m may be provided between the electrode 113g and the lower surface of the dielectric portion 113d. In the plasma processing apparatus 1G, the high-frequency power supply 31 may be electrically connected to the electrode 113m. The other configuration of the plasma processing apparatus 1G is the same as the corresponding configuration of the plasma processing apparatus 1F. Further, the operation of each component of the plasma processing apparatus 1G is the same as the operation of the corresponding part of the plasma processing apparatus 1F. Further, in the plasma processing apparatus 1G, the base 111 may be made of any one of the conductor, the dielectric, or the semiconductor.

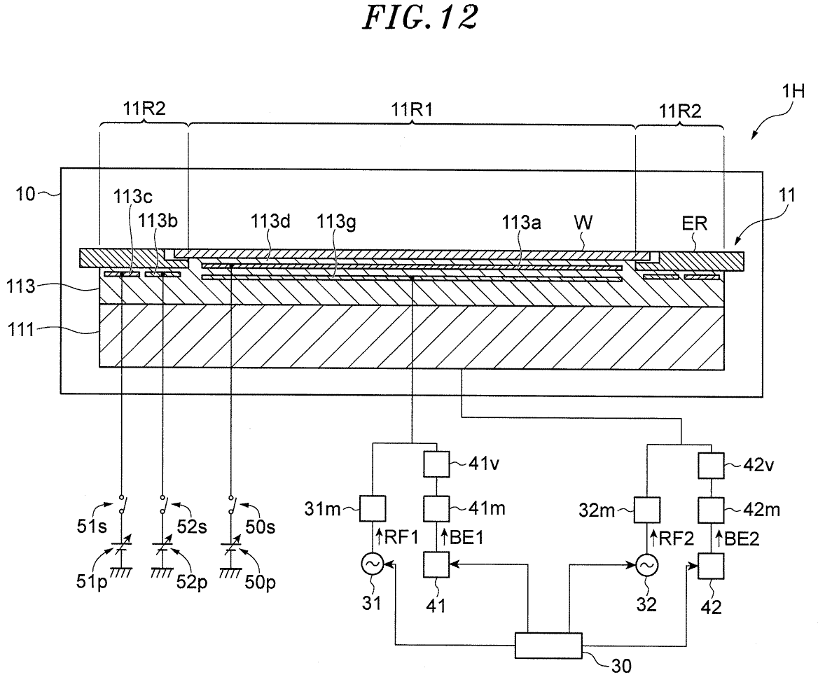

FIG. 12 is a schematic diagram of a plasma processing apparatus according to still yet another exemplary embodiment. Hereinafter, the difference of the plasma processing apparatus 1H illustrated in FIG. 12 from the plasma processing apparatus 1E will be described.

The plasma processing apparatus 1H does not have the electrode 113h. The high-frequency power supply 32 and the bias power supply 42 are electrically connected to the base 111. In the plasma processing apparatus 1H, the above-mentioned second and four examples regarding the adjustment of the power level P_{RF1} and the power level P_{RF2} in the cycle CY are used. The other configuration of the plasma processing apparatus 1H is the same as the corresponding configuration of the plasma processing apparatus 1E. Further, the other operation of each component of the plasma processing apparatus 1H is the same as the operation of the corresponding part of the plasma processing apparatus 1E.

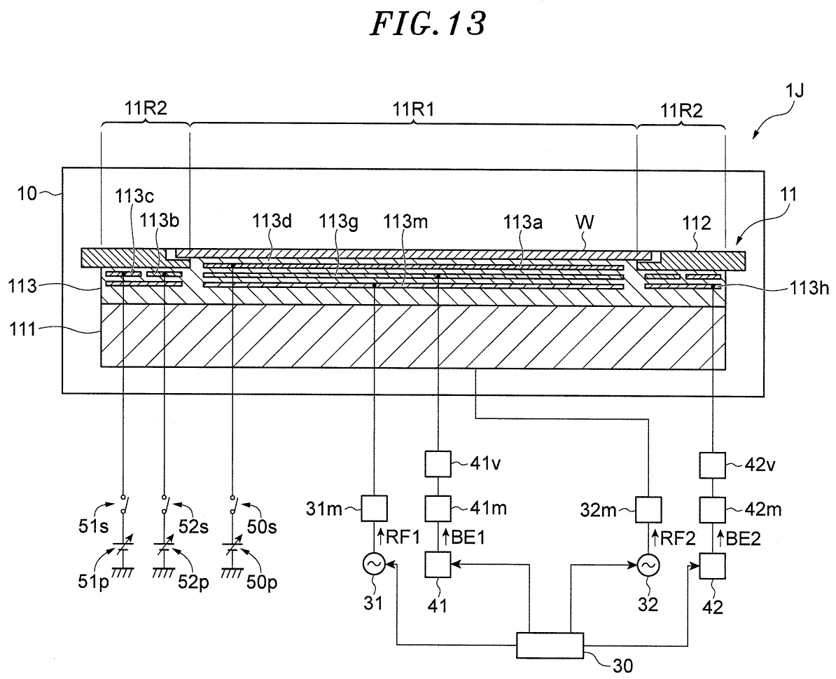

FIG. 13 is a schematic diagram of a plasma processing apparatus according to still yet another exemplary embodiment. Hereinafter, the difference of the plasma processing apparatus 1J illustrated in FIG. 13 from the plasma processing apparatus 1G will be described.

The plasma processing apparatus 1J does not have the electrode 113n. The high-frequency power supply 32 is electrically connected to the base 111. In the plasma processing apparatus 1J, the above-mentioned second and four examples regarding the adjustment of the power level P_{RF1} and the power level P_{RF2} in the cycle CY are used. The other configuration of the plasma processing apparatus 1J is the same as the corresponding configuration of the plasma processing apparatus 1G. Further, the other operation of each component of the plasma processing apparatus 1J is the same as the operation of the corresponding part of the plasma processing apparatus 1G.

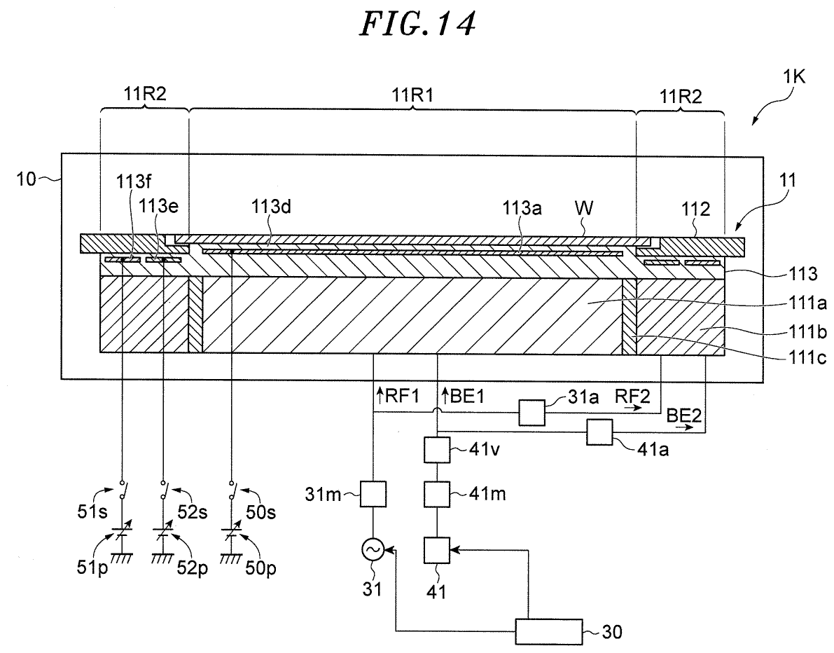

FIG. 14 is a schematic diagram of a plasma processing apparatus according to still yet another exemplary embodiment. Hereinafter, a difference between the plasma processing apparatus 1K illustrated in FIG. 14 and the plasma processing apparatus 1 will be described.

The plasma processing device 1K does not include the high-frequency power supply 32 and the bias power supply 42. In the plasma processing apparatus 1K, the high-frequency power generated by a single high-frequency power supply 31 is branched to generate the high-frequency power RF1 and the high-frequency power RF2. The high-frequency power RF1 is supplied to the first base 111a and the high-frequency power RF2 is supplied to the second base 111b.

A distribution ratio of the high-frequency power generated by the single high-frequency power supply 31 to the high-frequency power RF1 and high-frequency power RF2 is adjusted by an adjuster 31a. In the plasma processing apparatus 1K, the power level P_{RF1} of the high-frequency power RF1 and the power level P_{RF2} of the high-frequency power RF2 are set by adjusting the distribution ratio by the adjuster 31a. Further, in the plasma processing apparatuses 1B to 1K, the high-frequency power generated by the single high-frequency power supply 31 is branched, and as a result, the high-frequency power RF1 and the high-frequency power RF2 may be generated.

As illustrated in FIG. 14, the adjuster 31a may be connected between a node on an electrical path that connects the high-frequency power supply 31 to the first base 111a, and the second base 111b. The adjuster 31a may include a circuit with the variable impedance. This circuit may be configured by parallel connection of a plurality of serial circuits which each includes a fixed capacity condenser and a switching element. Alternatively, the adjuster 31a may be an attenuator configured to attenuate the high-frequency power supplied toward the second base 111b from the high-frequency power supply 31. Further, the adjuster 31a may be connected between the node and the first base 111a.

Further, in the plasma processing apparatus 1K, the electric bias energy generated by the single bias power supply 41 is branched to generate the electric bias energy BE1 and the electric bias energy BE2. The electric bias energy BE1 is supplied to the first base 111a and the electric bias energy BE2 is supplied to the second base 111b.

A distribution ratio of the electric bias energy BE1 and the electric bias energy BE2 of the electric bias energy generated by the single bias power supply 41 is adjusted by an adjuster 41a. In the plasma processing apparatus 1K, the level L_{BE1} of the electric bias energy BE1 and the level L_{BE2} of the electric bias energy BE2 are set by adjusting the distribution ration by the adjuster 41a. Further, even in the plasma processing apparatuses 1B to 1K, the electric bias energy generated by the single bias power supply 41 is branched, and as a result, the electric bias energy BE1 and the electric bias energy BE2 may be generated.

As illustrated in FIG. 14, the adjuster 41a may be connected between a node on an electrical path that connects the bias power supply 41 to the first base 111a, and the second base 111b. The adjuster 41a may include the circuit with the variable impedance. This circuit may be configured by parallel connection of the plurality of serial circuits which each includes the fixed capacity condenser and the switching element. Alternatively, the adjuster 41a may be an attenuator configured to attenuate the electric bias energy supplied toward the second base 111b from the bias power supply 41. Further, the adjuster 41a may be connected between the node and the first base 111a.

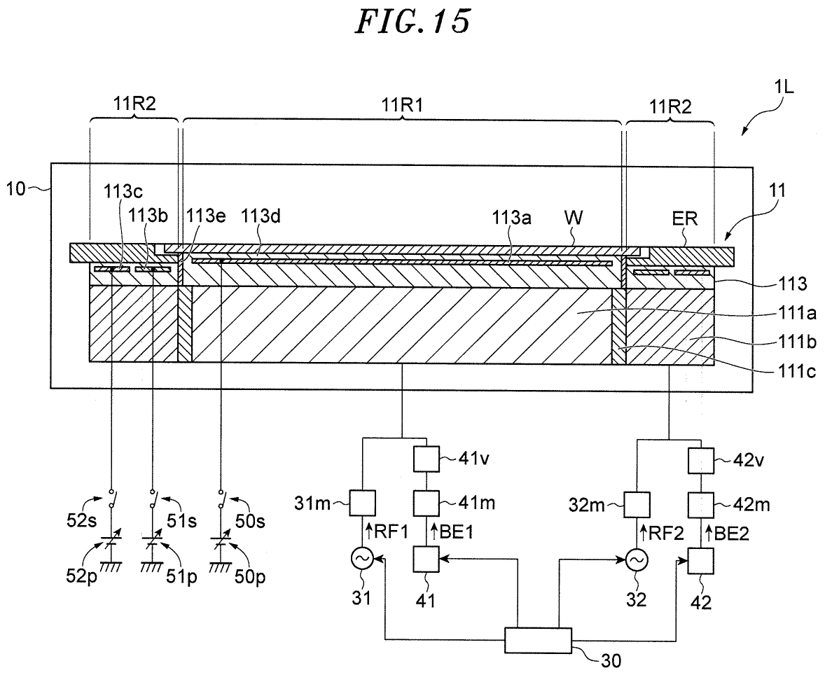

FIG. 15 is a schematic diagram of a plasma processing apparatus according to still yet another exemplary embodiment. Hereinafter, the difference of the plasma processing apparatus 1L illustrated in FIG. 15 from the plasma processing apparatus 1 will be described.

In the plasma processing apparatus 1L, the electrostatic chuck 113 includes a region 113e between the center and the periphery thereof. The region 113e may electrically separate the center and the periphery of the electrostatic chuck 113. The region 113e may be made of the insulator. Alternatively, the region 113e may be made of a dielectric different from a material of the dielectric portion 113d at the center of the electrostatic chuck 113 and the material of the dielectric portion 113d on the periphery of the electrostatic chuck 113. The region 113e may be made of a solution. Alternatively, the region 113e may be a space. Further, in the plasma processing apparatus 1L, the center and the periphery of the electrostatic chuck 113 may be made of different dielectrics. Further, in each of the plasma processing apparatuses according to various exemplary embodiments described above, the electrostatic chuck 113 may include the region 113e between the center and the periphery thereof.

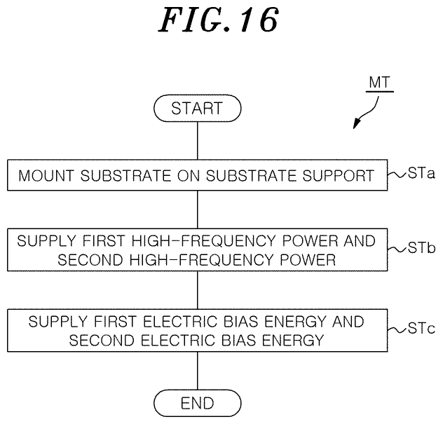

Hereinafter, a plasma processing method according to an exemplary embodiment will be described by referring to FIG. 16. FIG. 16 is a flowchart of a plasma processing method according to an exemplary embodiment. The plasma processing method (hereinafter, referred to as “method MT”) illustrated in FIG. 16 may be performed by using the plasma processing apparatuses according to various exemplary embodiments.

As illustrated in FIG. 16, the method MT is initiated in a process STa. In the process STa, a substrate is mounted on the substrate support 11. Then, in the method MT, a process STb and a process STc are performed in parallel. In a period in which the process STb and the process STc are performed, gas is supplied into the chamber 10 from the gas supply 20. Further, in the period in which the process STb and the process STc are performed, the pressure in the chamber 10 is reduced to designated pressure by the exhaust system 40.

In the process STb, in order to generate plasma from the gas in the chamber 10, the high-frequency power RF1 and the high-frequency power RF2 are supplied. In the process STc, the electric bias energy BE1 is supplied to the substrate W, and the electric bias energy BE2 is supplied to the edge ring ER. In the method MT, in the first period T1, the power level P_{RF1} of the high-frequency power RF1 or the power level P_{RF2} of the high-frequency power RF2 is set so as to reduce the difference between the top location of the sheath on the substrate W and the top location of the sheath on the edge ring ER.

Further, the level L_{BE2} of the electric bias energy BE2 may also be adjusted to reduce the difference between the top location of the sheath on the substrate W and the top location of the sheath on the edge ring ER within the cycle CY. Further, even in the second period T2, the power level P_{RF1} of the high-frequency power RF1 and/or the power level P_{RF2} of the high-frequency power RF2 may be adjusted. The description of the plasma processing apparatus 1 will be referenced regarding the adjustment of the level L_{BE2} of the electric bias energy BE2, and the adjustment of the power level P_{RF1} of the high-frequency power RF1 and the power level P_{RF2} of the high-frequency power RF2 may be controlled by the controller 1.

Hereinabove, various exemplary embodiments have been described, but the present disclosure is not limited to the exemplary embodiment, but various additions, omissions, substitutions, and changes may be made. Further, it is possible to form another exemplary embodiment by combining elements in different exemplary embodiments.

Here, various exemplary embodiments included in the present disclosure are disclosed in [E1] to [E16] below.

[E1]

A plasma processing apparatus comprising:

a chamber;

a substrate support provided in the chamber, and configured to support a substrate and an edge ring;

at least one high-frequency power supply configured to generate first high-frequency power coupled to plasma above the substrate via the substrate and second high-frequency power coupled to the plasma above the edge ring via the edge ring; and

at least one bias power supply configured to generate first electric bias energy supplied to the substrate and second electric bias energy supplied to the edge ring,

wherein each of the first electric bias energy and the second electric bias energy has a waveform repeatedly at a cycle having a time length of an inverse number of a bias frequency,

the cycle includes a first period in which voltage of each of the first electric bias energy and the second electric bias energy has a positive level with respect to an average value of the voltage within the cycle, and a second period in which the voltage of each of the first electric bias energy and the second electric bias energy has a negative level with respect to the average value, and

in the first period, a power level of the first high-frequency power or a power level of the second high-frequency power is set so as to reduce a difference between a top location of a sheath on the substrate and a top location of the sheath on the edge ring.

In the second period, the thickness of the sheath on the substrate and the thickness of the sheath on the edge ring are determined mainly by the level of the first electric bias energy and the level of the second electric bias energy. In the second period, by adjusting the level of the second electric bias energy, it is possible to reduce the difference between the top location of the sheath on the substrate and the top location of the sheath on the edge ring. Meanwhile, in the first period, the thickness of the sheath on the substrate and the thickness of the sheath on the edge ring are determined mainly by the power level of the first high-frequency power and the power level of the second high-frequency power. In the exemplary embodiment of [E1], in the first period, the power level of the first high-frequency power or the power level of the second high-frequency power is set so as to reduce the difference between the top location of the sheath on the substrate and the top location of the sheath on the edge ring. Therefore, in the first period T1, it is possible to reduce the difference between the top location of the sheath on the substrate W and the top location of the sheath on the edge ring ER. Therefore, according to the exemplary embodiment of [E1], it is possible to reduce the difference between the top location of the sheath on the substrate and the top location of the sheath on the edge ring within a cycle of the electric bias energy supplied to the edge ring.

[E2]

The plasma processing apparatus of [E1], wherein the level of the second electric bias energy is set to increase with a decrease in thickness of the edge ring.

[E3]

The plasma processing apparatus of [E2], wherein when the thickness of the edge ring is larger than a predetermined value, the power level of the second high-frequency power supplied in the first period is set to a power level lower than a reference power level of the second high-frequency power to be set in the first period when the thickness of the edge ring is the predetermined value.

[E4]

The plasma processing apparatus of [E3], wherein when the thickness of the edge ring is larger than the predetermined value, the power level of the second high-frequency power supplied in the second period is set to a power level higher than the reference power level of the second high-frequency power to be set in the second period when the thickness of the edge ring is the predetermined value.

[E5]

The plasma processing apparatus of [E2], wherein when the thickness of the edge ring is larger than a predetermined value, the power level of the first high-frequency power supplied in the first period is set to a power level higher than the reference power level of the first high-frequency power to be set in the first period when the thickness of the edge ring is the predetermined value.

[E6]

The plasma processing apparatus of [E5], wherein when the thickness of the edge ring is larger than the predetermined value, the power level of the first high-frequency power supplied in the second period is set to a power level lower than the reference power level of the first high-frequency power to be set in the second period when the thickness of the edge ring is the predetermined value.

[E7]

The plasma processing apparatus of [E2], wherein when the thickness of the edge ring is smaller than the predetermined value, the power level of the second high-frequency power supplied in the first period is set to a power level higher than the reference power level of the second high-frequency power to be set in the first period when the thickness of the edge ring is the predetermined value.

[E8]

The plasma processing apparatus of [E7], wherein when the thickness of the edge ring is smaller than the predetermined value, the power level of the second high-frequency power supplied in the second period is set to a power level lower than the reference power level of the second high-frequency power to be set in the second period when the thickness of the edge ring is the predetermined value.

[E9]

The plasma processing apparatus of [E2], wherein when the thickness of the edge ring is smaller than the predetermined value, the power level of the first high-frequency power supplied in the first period is set to a power level lower than the reference power level of the first high-frequency power to be set in the first period when the thickness of the edge ring is the predetermined value.

[E10]

The plasma processing apparatus of [E9], wherein when the thickness of the edge ring is smaller than the predetermined value, the power level of the first high-frequency power supplied in the second period is set to a power level higher than the reference power level of the first high-frequency power to be set in the second period when the thickness of the edge ring is the predetermined value.

[E11]

The plasma processing apparatus of any one of [E1] to [E10], wherein the at least one high-frequency power supply comprises a first high-frequency power supply configured to generate the first high-frequency power and a second high-frequency power supply configured to generate the second high-frequency power.

[E12]

The plasma processing apparatus of any one of [E1] to [E10], wherein the at least one high-frequency power supply comprises a single high-frequency power supply, and the plasma processing apparatus further comprises an adjuster configured to adjust a distribution ratio of high-frequency power generated by the single high-frequency power supply to the first high-frequency power and the second high-frequency power.

[E13]

The plasma processing apparatus of any one of [E1] to [E12], wherein the at least one bias power supply comprises a first bias power supply configured to generate the first electric bias energy and a second bias power supply configured to generate the second electric bias energy.

[E14]

The plasma processing apparatus of any one of [E1] to [E12], wherein the at least one bias power supply comprises a single bias power supply, and

the plasma processing apparatus further comprises an adjuster configured to adjust a distribution ratio of electric bias energy generated by the single bias power supply to the first electric bias energy and the second electric bias energy.

[E15]

The plasma processing apparatus of any one of [E1] to [E14], wherein each of the first electric bias energy and the second electric bias energy is high-frequency bias power or a pulse of voltage periodically generated at a time interval having a time length of an inverse number of the bias frequency.

[E16]

A plasma processing method comprising:

mounting a substrate on a substrate support in a chamber of a plasma processing apparatus, in which an edge ring is mounted on the substrate support,

supplying first high-frequency power coupled to plasma above the substrate via the substrate and second high-frequency power coupled to the plasma above the edge ring via the edge ring; and

supplying first electric bias energy to the substrate and second electric bias energy to the edge ring,

wherein each of the first electric bias energy and the second electric bias energy has a waveform repeatedly at a cycle having a time length of an inverse number of a bias frequency,

the cycle includes a first period in which voltage of each of the first electric bias energy and the second electric bias energy has a positive level with respect to an average value of the voltage within the cycle, and a second period in which the voltage of each of the first electric bias energy and the second electric bias energy has a negative level with respect to the average value, and

in the first period, a power level of the first high-frequency power or a power level of the second high-frequency power is set so as to reduce a difference between a top location of a sheath on the substrate and a top location of the sheath on the edge ring.

From the above description, it will be understood that various exemplary embodiments of the present disclosure are described in the present specification for the purpose of the description, and that various changes can be made without departing from the scope and the spirit of the present disclosure. Therefore, it is not intended to limit the various exemplary embodiments disclosed in the present specification, and the true scope and spirit are indicated by the appended claims.

1. A plasma processing apparatus comprising:
a chamber;
a substrate support provided in the chamber, and configured to support a substrate and an edge ring;
at least one high-frequency power supply configured to generate first high-frequency power coupled to plasma above the substrate via the substrate and second high-frequency power coupled to the plasma above the edge ring via the edge ring; and
at least one bias power supply configured to generate first electric bias energy supplied to the substrate and second electric bias energy supplied to the edge ring,
wherein each of the first electric bias energy and the second electric bias energy has a waveform repeatedly at a cycle having a time length of an inverse number of a bias frequency,
the cycle includes a first period in which voltage of each of the first electric bias energy and the second electric bias energy has a positive level with respect to an average value of the voltage within the cycle, and a second period in which the voltage of each of the first electric bias energy and the second electric bias energy has a negative level with respect to the average value, and
in the first period, a power level of the first high-frequency power or a power level of the second high-frequency power is set so as to reduce a difference between a top location of a sheath on the substrate and a top location of the sheath on the edge ring.

2. The plasma processing apparatus of claim 1, wherein the level of the second electric bias energy is set to increase with a decrease in thickness of the edge ring.

3. The plasma processing apparatus of claim 2, wherein when the thickness of the edge ring is larger than a predetermined value, the power level of the second high-frequency power supplied in the first period is set to a power level lower than a reference power level of the second high-frequency power to be set in the first period when the thickness of the edge ring is the predetermined value.

4. The plasma processing apparatus of claim 3, wherein when the thickness of the edge ring is larger than the predetermined value, the power level of the second high-frequency power supplied in the second period is set to a power level higher than the reference power level of the second high-frequency power to be set in the second period when the thickness of the edge ring is the predetermined value.

5. The plasma processing apparatus of claim 2, wherein when the thickness of the edge ring is larger than a predetermined value, the power level of the first high-frequency power supplied in the first period is set to a power level higher than the reference power level of the first high-frequency power to be set in the first period when the thickness of the edge ring is the predetermined value.

6. The plasma processing apparatus of claim 5, wherein when the thickness of the edge ring is larger than the predetermined value, the power level of the first high-frequency power supplied in the second period is set to a power level lower than the reference power level of the first high-frequency power to be set in the second period when the thickness of the edge ring is the predetermined value.

7. The plasma processing apparatus of claim 2, wherein when the thickness of the edge ring is smaller than the predetermined value, the power level of the second high-frequency power supplied in the first period is set to a power level higher than the reference power level of the second high-frequency power to be set in the first period when the thickness of the edge ring is the predetermined value.

8. The plasma processing apparatus of claim 7, wherein when the thickness of the edge ring is smaller than the predetermined value, the power level of the second high-frequency power supplied in the second period is set to a power level lower than the reference power level of the second high-frequency power to be set in the second period when the thickness of the edge ring is the predetermined value.

9. The plasma processing apparatus of claim 2, wherein when the thickness of the edge ring is smaller than the predetermined value, the power level of the first high-frequency power supplied in the first period is set to a power level lower than the reference power level of the first high-frequency power to be set in the first period when the thickness of the edge ring is the predetermined value.

10. The plasma processing apparatus of claim 9, wherein when the thickness of the edge ring is smaller than the predetermined value, the power level of the first high-frequency power supplied in the second period is set to a power level higher than the reference power level of the first high-frequency power to be set in the second period when the thickness of the edge ring is the predetermined value.

11. The plasma processing apparatus of claim 1, wherein the at least one high-frequency power supply comprises a first high-frequency power supply configured to generate the first high-frequency power and a second high-frequency power supply configured to generate the second high-frequency power.

12. The plasma processing apparatus of claim 1, wherein the at least one high-frequency power supply comprises a single high-frequency power supply, and
the plasma processing apparatus further comprises an adjuster configured to adjust a distribution ratio of high-frequency power generated by the single high-frequency power supply to the first high-frequency power and the second high-frequency power.

13. The plasma processing apparatus of claim 1, wherein the at least one bias power supply comprises a first bias power supply configured to generate the first electric bias energy and a second bias power supply configured to generate the second electric bias energy.

14. The plasma processing apparatus of claim 1, wherein the at least one bias power supply comprises a single bias power supply, and
the plasma processing apparatus further comprises an adjuster configured to adjust a distribution ratio of electric bias energy generated by the single bias power supply to the first electric bias energy and the second electric bias energy.

15. The plasma processing apparatus of claim 1, wherein each of the first electric bias energy and the second electric bias energy is high-frequency bias power or a pulse of voltage periodically generated at a time interval having a time length of an inverse number of the bias frequency.

16. A plasma processing method comprising:
mounting a substrate on a substrate support in a chamber of a plasma processing apparatus, in which an edge ring is mounted on the substrate support,
supplying first high-frequency power coupled to plasma above the substrate via the substrate and second high-frequency power coupled to the plasma above the edge ring via the edge ring; and
supplying first electric bias energy to the substrate and second electric bias energy to the edge ring,
wherein each of the first electric bias energy and the second electric bias energy has a waveform repeatedly at a cycle having a time length of an inverse number of a bias frequency,
the cycle includes a first period in which voltage of each of the first electric bias energy and the second electric bias energy has a positive level with respect to an average value of the voltage within the cycle, and a second period in which the voltage of each of the first electric bias energy and the second electric bias energy has a negative level with respect to the average value, and
in the first period, a power level of the first high-frequency power or a power level of the second high-frequency power is set so as to reduce a difference between a top location of a sheath on the substrate and a top location of the sheath on the edge ring.
